(19) United States
(12) Patent Application Publication
(10) Pub. No.: US 2012/0263941 A1
(43) Pub. Date: Oct. 18, 2012

(54) COATED ARTICLE AND METHOD FOR MAKING THE SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); CONG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/177,950

(22) Filed: Jul. 7, 2011

(30) Foreign Application Priority Data
Apr. 18, 2011 (CN) 201110096490.6

(51) Int. Cl. B32B 5/00; B32B 15/04; C23C 14/35; B32B 18/00; B32B 17/06; C01B 35/00; B32B 9/04

(52) U.S. Cl. 428/336; 423/276; 428/469; 428/688; 428/446; 428/432; 204/192.16

(57) ABSTRACT

A coated article is described. The coated article includes a substrate, and a hydrophobic film formed on the substrate. The hydrophobic film is a non-crystalline boron-carbon-nitrogen layer formed by magnetron sputtering. A method for making the coated article is also described.

### CROSS-REFERENCE TO RELATED APPLICATIONS

This application is one of the two related co-pending U.S. patent applications listed below. All listed applications have the same assignee. The disclosure of each of the listed applications is incorporated by reference into another listed application.

| Attorney | | |
|---|---|---|
| Docket | | |
| No. | Title | Inventors |
| US 35694 | COATED ARTICLE AND METHOD | HSIN-PEI CHANG |
| | FOR MAKING THE SAME | et al. |
| US 35695 | COATED ARTICLE AND METHOD | HSIN-PEI CHANG |
| | FOR MAKING THE SAME | et al. |

### BACKGROUND

1. Technical Field

The present disclosure relates to coated articles, particularly to a coated article having a hydrophobic effect and a method for making the coated article.

2. Description of Related Art

Many electronic device housings are coated with a hydrophobic film. The hydrophobic film is commonly painted on the housing with paints containing organic macromolecule hydrophobic substances. However, the painted film has a low hardness, poor abrasion resistance, and a low temperature resistance. Additionally, the hydrophobic film may contain residual free formaldehyde, which is not environmentally friendly.

Therefore, there is room for improvement within the art.

### BRIEF DESCRIPTION OF THE FIGURES

Many aspects of the disclosure can be better understood with reference to the following figures. The components in the figures are not necessarily drawn to scale, the emphasis instead being placed upon clearly illustrating the principles of the disclosure. Moreover, in the drawings like reference numerals designate corresponding parts throughout the several views.

FIG. 1 is a cross-sectional view of an exemplary embodiment of a coated article.

FIG. 2 is an overlook view of an exemplary embodiment of a vacuum sputtering device.

### DETAILED DESCRIPTION

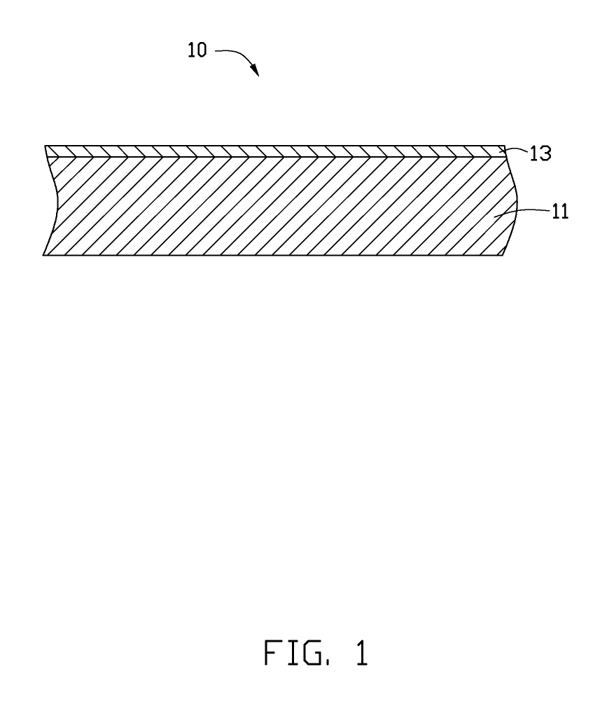

FIG. 1 shows a coated article 10 according to an exemplary embodiment. The coated article 10 includes a substrate 11, and a hydrophobic film 13 formed on a surface of the substrate 11.

The substrate 11 may be made of metal or non-metal material. The metal material may be stainless steel, aluminum, or aluminum alloy. The non-metal material may be ceramic or glass.

The hydrophobic film 13 is a non-crystalline boron-carbon-nitrogen (B-C-N) layer.

The contact angle between the hydrophobic film 13 and water droplet has been tested on the coated article 10. The contact angle is defined by an included angle between the surface of the hydrophobic film 13 and the tangent line of the water droplet. The test indicates that the contact angle between the hydrophobic film 13 and the water droplet is about 102°-110°. Thus, the hydrophobic film 13 has a good hydrophobic effect.

The hydrophobic film 13 has a thickness of about 250 nm-500 nm, which is thin. The hydrophobic film 13 may be formed by an environmentally friendly vacuum sputtering method. In comparison to the painted hydrophobic film, the hydrophobic film 13 in this embodiment has a high hardness, good abrasion resistance, and high temperature resistance. Furthermore, the hydrophobic film 13 is tightly bonded to the substrate 11.

A method for making the coated article 10 may include the following steps:

The substrate 11 is pre-treated, such pre-treating process may include the following steps:

The substrate 11 is cleaned in an ultrasonic cleaning device (not shown) filled with ethanol or acetone.

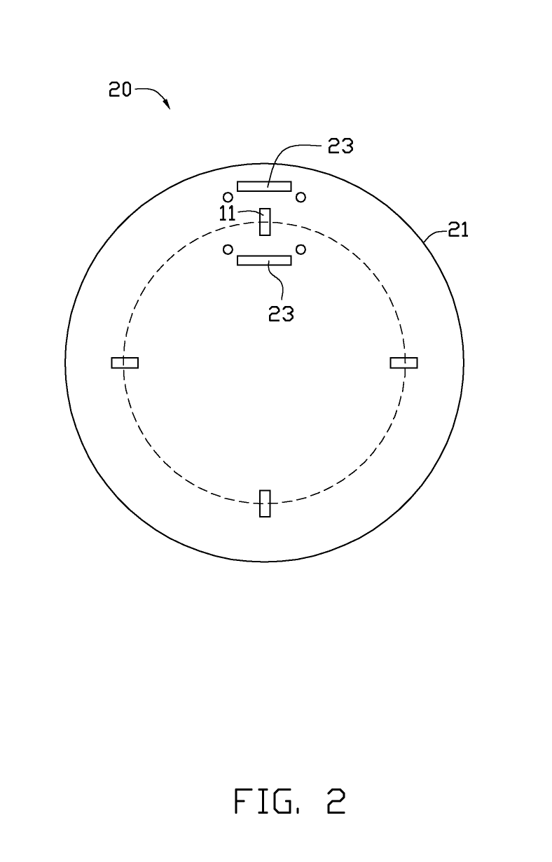

The substrate 11 is plasma cleaned. Referring to FIG. 2, the substrate 11 may be positioned in a coating chamber 21 of a vacuum sputtering device 20. The coating chamber 21 is fixed with boron nitride targets 23 therein. The coating chamber 21 is then evacuated to about 4.0×10⁻³ Pa. Argon gas having a purity of about 99.999% may be used as a working gas and is injected into the coating chamber 21 at a flow rate of about 500 standard-state cubic centimeters per minute (sccm). The substrate 11 may have a negative bias voltage of about −200 V to about −500 V, then high-frequency voltage is produced in the coating chamber 21 and the argon gas is ionized to plasma. The plasma then strikes the surface of the substrate 11 to clean the surface of the substrate 11. Plasma cleaning of the substrate 11 may take about 3 minutes (min)-10 min. The plasma cleaning process enhances the bond between the substrate 11 and the hydrophobic film 13. The boron nitride targets 23 are unaffected by the pre-cleaning process.

The hydrophobic film 13 may be magnetron sputtered on the pretreated substrate 11. Magnetron sputtering of the hydrophobic film 13 is implemented in the coating chamber 21. The inside of the coating chamber 21 is heated to about 150° C.-420° C. Acetylene (C₂H₂) may be used as a reaction gas and is injected into the coating chamber 21 at a flow rate of about 300 sccm-500 sccm. Argon gas may be used as a working gas and is injected into the coating chamber 21 at a flow rate of about 300 sccm-500 sccm. Power at a level of 0.2 kilowatt (KW)-1 KW is applied to the boron nitride targets 23, and then boron nitride atoms are sputtered off from the boron nitride targets 23. The boron nitride atoms and acetylene atoms are ionized in an electrical field in the coating chamber 21. The ionized boron nitride then chemically reacts with the ionized acetylene to deposit the hydrophobic film 13 on the substrate 11. During the depositing process, the substrate 11 may have a negative bias voltage of about −50 V to about −300 V. Depositing of the hydrophobic film 13 may take about 20 min-60 min.

Specific examples of making the coated article 10 are described as following. The pre-treating process of ultrasonic cleaning the substrate 11 in these specific examples may be substantially the same as previously described so it is not described here again. Additionally, the magnetron sputtering process of the hydrophobic film 13 in the specific examples is substantially the same as described above, and the specific examples mainly emphasize the different process parameters of making the coated article 10.

### Example 1

The substrate 11 is made of glass.

Plasma cleaning of the substrate 11: the flow rate of Ar is 500 sccm; the substrate 11 has a negative bias voltage of −250 V; plasma cleaning of the substrate 11 takes 5 min.

Sputtering to form the hydrophobic film 13 on the substrate 11: the flow rate of Ar is 500 sccm, the flow rate of C₂H₂ is 300 sccm; the substrate 11 has a negative bias voltage of −150 V; the boron nitride targets 23 are applied with a power of 1 KW; the internal temperature of the coating chamber 21 is 250° C.; sputtering of the hydrophobic film 13 takes 40 min.

The hydrophobic film 13 of example 1 has a thickness of 280 nm. The contact angle between the hydrophobic film 13 and water droplet is 103°.

### Example 2

The substrate 11 is made of stainless steel.

Plasma cleaning of the substrate 11: the flow rate of Ar is 500 sccm; the substrate 11 has a negative bias voltage of −250 V; plasma cleaning of the substrate 11 takes 5 min.

Sputtering to form the hydrophobic film 13 on the substrate 11: the flow rate of Ar is 300 sccm, the flow rate of C₂H₂ is 400 sccm; the substrate 11 has a negative bias voltage of −200 V; the boron nitride targets 23 are applied with a power of 1 KW; the internal temperature of the coating chamber 21 is 300° C.; sputtering of the hydrophobic film 13 takes 60 min.

The hydrophobic film 13 of example 2 has a thickness of 400 nm. The contact angle between the hydrophobic film 13 and water droplet is 110°.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article, comprising:
a substrate; and
a hydrophobic film formed on the substrate, the hydrophobic film being a non-crystalline boron-carbon-nitrogen layer formed on the substrate layer by magnetron sputtering.

2. The coated article as claimed in claim 1, wherein the hydrophobic film has a thickness of about 250 nm-500 nm.

3. The coated article as claimed in claim 1, wherein the substrate is made of metal or non-metal material.

4. The coated article as claimed in claim 3, wherein the metal material is stainless steel, aluminum, or aluminum alloy.

5. The coated article as claimed in claim 3, wherein the non-metal material is ceramic or glass.

6. The coated article as claimed in claim 1, wherein the hydrophobic film has a contact angle of about 102°-110° with water droplets.

7. A method for making a coated article, comprising:
providing a substrate; and
forming a hydrophobic film on the substrate by magnetron sputtering, using acetylene as a reaction gas and using boron nitride target; the hydrophobic film being a non-crystalline boron-carbon-nitrogen layer.

8. The method as claimed in claim 7, wherein the acetylene has a flow rate of about 300 sccm-500 sccm; the boron nitride target is applied with a power of 0.2 KW-1 KW; magnetron sputtering of the hydrophobic film uses argon as a working gas, the argon has a flow rate of about 300 sccm-500 sccm; magnetron sputtering of the hydrophobic film is conducted at a temperature of about 150° C.-420° C. and takes about 20 min-60 min.

9. The method as claimed in claim 8, wherein the substrate has a negative bias voltage of about −50V to about −300V during magnetron sputtering of the hydrophobic film.

10. The method as claimed in claim 7, further comprising a step of pre-treating the substrate before forming the hydrophobic film.

11. The method as claimed in claim 10, wherein the pre-treating process comprises ultrasonic cleaning the substrate and plasma cleaning the substrate.

12. The method as claimed in claim 11, wherein plasma cleaning the substrate uses argon as a working gas, the argon has a flow rate of about 500 sccm; the substrate has a negative bias voltage of −200 V to about −500 V; plasma cleaning of the substrate takes about 3 min-10 min.

13. The method as claimed in claim 7, wherein the substrate is made of metal or non-metal material.

14. The method as claimed in claim 13, wherein the metal material is stainless steel, aluminum, or aluminum alloy.

15. The method as claimed in claim 13, wherein the non-metal material is ceramic or glass.

16. The method as claimed in claim 7, wherein the hydrophobic film has a thickness of about 250 nm-500 nm.

17. The method as claimed in claim 7, wherein the hydrophobic film has a contact angle of about 102°-110° with water droplets.
